(19) United States
(12) Patent Application Publication
(10) Pub. No.: US 2022/0262785 A1
(43) Pub. Date: Aug. 18, 2022

(54) INTEGRATED CIRCUIT INCLUDING SIGNAL LINE AND POWER LINE AND METHOD OF DESIGNING THE SAME

(71) Applicant: SAMSUNG ELECTRONICS CO., LTD., Suwon-si (KR)

(72) Inventors: Jisu YU, Seoul (KR); Jaewoo SEO, Seoul (KR); Hyeongyu YOU, Hwaseong-si (KR); Minjae JEONG, Yongin-si (KR)

(73) Assignee: SAMSUNG ELECTRONICS CO., LTD., Suwon-si (KR)

(21) Appl. No.: 17/540,345

(22) Filed: Dec. 2, 2021

(30) Foreign Application Priority Data
Feb. 18, 2021 (KR) 10-20210022028

(51) Int. Cl. H01L 27/02; H01L 23/528; G06F 30/392

(52) U.S. Cl. CPC H01L 27/0207; G06F 30/392; H01L 23/5286

(57) ABSTRACT

An integrated circuit (IC) includes: a plurality of gate electrodes extending in a first direction and arranged in a second direction that is orthogonal to the first direction; a plurality of first power lines extending in the first direction to supply power to the standard cell, and respectively placed to be adjacent to first sides of the gate electrodes; and a plurality of signal lines extending in the first direction to transfer an input signal or an output signal of the standard cell, and respectively placed to be adjacent to second sides of the gate electrodes.

### CROSS-REFERENCE TO RELATED APPLICATION

This application is based on and claims priority under 35 U.S.C. § 119 to Korean Patent Application No. 10-2021-0022028, filed on Feb. 18, 2021, in the Korean Intellectual Property Office, the disclosure of which is incorporated by reference herein in its entirety.

### BACKGROUND

The embodiments of the inventive concept relate to an integrated circuit (IC), and more particularly, to an IC including a signal line and a power line and a method of designing the same.

An IC may include a plurality of standard cells aligned along a plurality of rows. In addition, the IC may include a power distributed network (PDN) configured to supply power to the standard cells. As the degree of circuit integration increases, a resistance of the PDN relatively increases, and thus, an area occupied by the PDN to supply stable power to the standard cells may need to be increased. Conductive wirings constituting the PDN may be formed in a same wiring layer as conductive wirings for routing of the standard cells, and thus, an efficient placement between the conductive wirings constituting the PDN and the conductive wirings for routing of the standard cells may be required.

### SUMMARY

The embodiments of the inventive concept provide an integrated circuit (IC) in which a power line and a signal line are placed at pre-defined locations and a method of designing the same.

According to an aspect of the embodiments, there is provided an IC including: a plurality of gate electrodes extending in a first direction and arranged in a second direction that is orthogonal to the first direction; a plurality of first power lines extending in the first direction to supply power to the standard cell, and respectively placed to be adjacent to first sides of the gate electrodes; and a plurality of signal lines extending in the first direction to transfer an input signal or an output signal of the standard cell, and respectively placed to be adjacent to second sides of the gate electrodes.

According to another aspect of the embodiments, there is provided an IC including: a plurality of gate electrodes aligned along a plurality of first tracks extending in a first direction and arranged in a second direction orthogonal to the first direction; at least one signal line aligned along at least one second track, respectively, located at a pre-defined side of at least one of the gate electrodes, among a plurality of second tracks extending in the first direction and arranged in the second direction, to transfer an input signal or an output signal of the standard cells; and at least one first power line aligned along at least one of the second tracks except the second track located at the pre-defined side, to supply power to the standard cells.

According to another aspect of the embodiments, there is provided a method of designing an IC, the method including: placing, in a first row, a first standard cell comprising at least one first power line formed at least one first side of at least one gate electrode extending in a first direction from a cell library, based on input data defining the IC; placing at least one signal line, extending in the first direction, at least one second side of the gate electrode; and generating output data defining a layout of the IC.

### BRIEF DESCRIPTION OF DRAWINGS

Embodiments will be more clearly understood from the following detailed description taken in conjunction with the accompanying drawings in which:

FIG. 1 is a layout diagram of an integrated circuit (IC) according to an embodiment;

FIG. 2 is a layout diagram of a standard cell according to an embodiment;

FIG. 3 is a layout diagram of an IC according to an embodiment;

FIG. 4 is a layout diagram of a standard cell according to an embodiment;

FIGS. 5A to 5D are cross-sectional views of a structure of a standard cell according to an embodiment;

FIG. 6 is a layout diagram of a standard cell according to an embodiment;

FIG. 7 is a layout diagram of a power distributed network (PDN) according to an embodiment;

FIG. 8 is a flowchart of a method of fabricating an IC, according to an embodiment;

FIG. 9 is a flowchart of a method of designing an IC, according to an embodiment;

FIG. 10 is a block diagram of a system on chip (SoC) according to an embodiment; and

FIG. 11 is a block diagram of a computing system including a memory storing a program, according to an embodiment.

### DETAILED DESCRIPTION

Hereinafter, various embodiments of the inventive concept will be described with reference to the accompanying drawings. The embodiments described herein are all example embodiments, and thus, the inventive concept is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

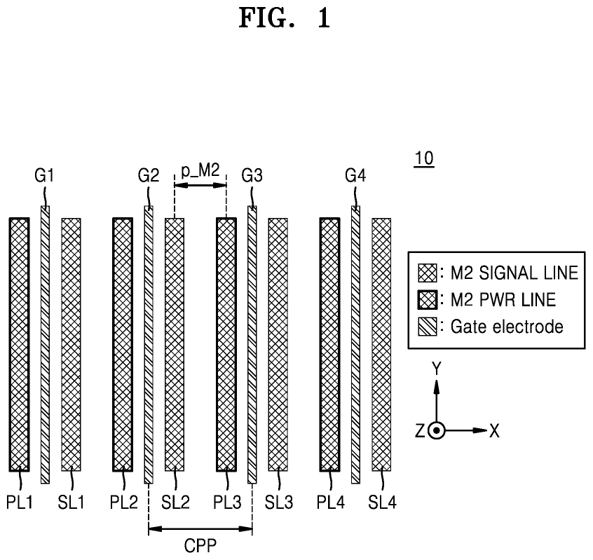

FIG. 1 is a layout diagram of an integrated circuit (IC) 10, according to an embodiment. Particularly, FIG. 1 shows a layout on an X-Y plane on which a plurality of gate electrodes, e.g., first to fourth gate electrodes G1 to G4, and a plurality of wirings PL1 to PL4 and SL1 to SL4 included in the IC 10 are placed.

Referring to FIG. 1, the gate electrodes G1 to G4 may be separated from each other with a first pitch CPP, and extend in a Y-axis direction. Although not shown in FIG. 1, the IC 10 may include a plurality of transistors, and the gate electrodes G1 to G4 may be formed in a structure corresponding to gate terminals of the transistors included in the IC 10.

Referring to FIG. 1, the wirings PL1 to PL4 and SL1 to SL4 may be separated from each other with a second pitch p_M2, and extend in the Y-axis direction. The wirings PL1 to PL4 and SL1 to SL4 may be formed in the same wiring layer, e.g., a second wiring layer M2. The wirings PL1 to PL4 and SL1 to SL4 may include upper power lines PL1 to PL4 and signal lines SL1 to SL4. Although not shown in FIG. 1, the IC 10 may include a plurality of various standard cells. The standard cells may have a structure conforming to a pre-defined standard, and may be aligned and placed in a plurality of rows. The standard cells may receive power from the upper power lines PL1 to PL4, and receive an input signal or transmit an output signal through the signal lines SL1 to SL4.

The upper power lines PL1 to PL4 may be placed to be adjacent to first sides (e.g., left sides) of the gate electrodes G1 to G4, respectively. The present embodiment is not limited to FIG. 1, and unlike shown in FIG. 1, the upper power lines PL1 to PL4 may be placed to be adjacent to right sides of the gate electrodes G1 to G4, respectively. That is, in some embodiments, at least one upper power line may be placed between gate electrodes adjacent to each other in an X-axis direction.

According to an embodiment, the signal lines SL1 to SL4 may be placed to be adjacent to second sides (e.g., right sides) of the gate electrodes G1 to G4, respectively. The present embodiment is not limited to FIG. 1, and unlike shown in FIG. 1, the signal lines SL1 to SL4 may be placed to be adjacent to the left sides of the gate electrodes G1 to G4, respectively.

In some embodiments, the first pitch CPP may be double the second pitch p_M2. That is, a gear ratio (GR) indicating a ratio of a pitch of gate electrodes to a pitch of wirings may be 2:1. The GR may affect pin access performance, routing performance, power supply performance, and the like. When the GR is 2:1, two wirings may be placed between adjacent gate electrodes. The IC 10 according to an embodiment may use, as a power line, at least one of wirings placed between adjacent gate electrodes to reduce a resistance of a path through which power is supplied to a standard cell. In addition, the IC 10 according to an embodiment may have signal lines and power lines placed at pre-defined locations, thereby providing improved routing performance and power supply performance.

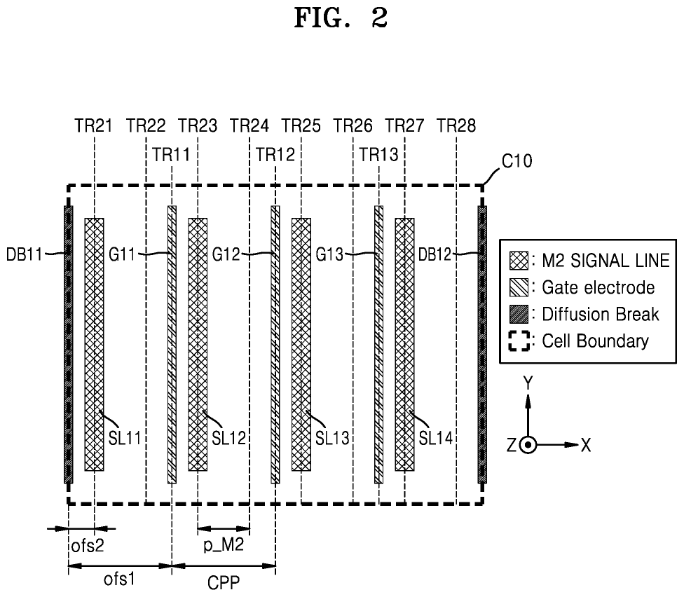

FIG. 2 is a layout diagram of a standard cell C10, according to an embodiment. Referring to FIG. 2, the standard cell C10 may be included in, for example, the IC 10 of FIG. 1. A standard cell is a unit of a layout included in an inventive concept, and may be simply referred to as a cell in the present specification. A boundary of the standard cell C10 may be determined by cell separation structures DB11 and DB12. A cell separation structure may be inserted to reduce an influence, e.g., a local layout effect (LLE), between adjacent standard cells. The cell separation structure may separate an active region between adjacent cells and be filled with an insulator. In some embodiments, the cell separation structure may separate a diffusion region between adjacent cells by removing at least a portion of the diffusion region and/or the active region. The cell separation structures DB11 and DB12 may be referred to as diffusion breaks. Each of the cell separation structures DB11 and DB12 may be formed by a single diffusion break or double diffusion breaks.

The standard cell C10 may include a plurality of gate electrodes G11 to G13 and a plurality of signal lines SL11 to SL14. The gate electrodes G11 and G13 are the leftmost and rightmost gate electrodes, respectively, in the standard cell C10. The gate electrodes G11 to G13 may be respectively aligned and placed on first tracks TR11 to TR13 extending in the Y-axis direction. The first tracks TR11 to TR13 may be separated from each other with the first pitch CPP. The signal lines SL11 to SL14 may be aligned and placed on at least one of second tracks TR21 to TR28 extending in the Y-axis direction. For example, the signal lines SL11 to SL14 may be aligned and placed along the second tracks TR21, TR23, TR25, and TR27 located at the second sides (e.g., right sides) of the cell separation structure DB11 and the gate electrodes G11 to G13, respectively. The second tracks TR21 to TR28 may be separated from each other with the second pitch p_M2.

As shown in FIG. 2, the first tracks TR11 to TR13 may be aligned from a location separated by a first offset ofs1 from a cell boundary of the standard cell C10. The second tracks TR21 to TR28 may be aligned from a location separated by a second offset ofs2 from the cell boundary of the standard cell C10. In some embodiments, the first offset ofs1 may be the same as the first pitch CPP, and the second offset ofs2 may be the same as the second pitch p_M2. However, the present embodiment is not limited thereto.

Referring to the standard cell C10 of FIG. 2, signal lines may not be placed on pre-defined second tracks TR22, TR24, TR26, and TR28. For example, signal lines may not be placed on the second tracks TR22, TR24, TR26, and TR28 located at the first sides (e.g., left sides) of the gate electrodes G11 to G13 and the cell separation structure DB12, respectively. Therefore, because power lines may be placed along the pre-defined second tracks TR22, TR24, TR26, and TR28, a resistance of a path through which power is supplied to the standard cell C10 may be reduced.

It is noted herein that the first side (e.g., left side) of a gate electrode or cell separation structure may be further defined as a side closer to the gate electrode or cell separation structure than another gate electrode or cell separation structure adjacent in a first direction (e.g., left direction). Likewise, the second side (e.g., right side) of a gate electrode or cell separation structure may be further defined as a side closer to the gate electrode or cell separation structure than another gate electrode or cell separation structure adjacent in a second direction (e.g., right direction).

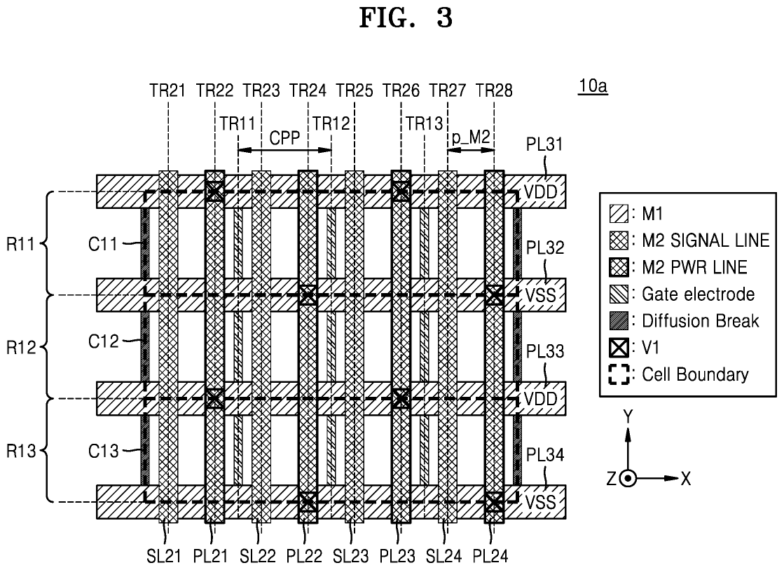

FIG. 3 is a layout diagram of an IC 10a according to an embodiment. Particularly, FIG. 3 is a top view, on the X-Y plane, of the IC 10a including a plurality of standard cells C11, C12, and C13. In the present specification, a plane formed by the X-axis and the Y-axis may be referred to as a horizontal plane, a component placed relatively higher in a +Z-axis direction than a different component may be referred to as being located above the different component, and a component placed relatively lower in a −Z-axis direction than a different component may be referred to as being located under the different component. In the drawings of the present specification, only some layers may be shown for convenience of drawing, and to indicate a connection between a pattern of a wiring layer and a pattern of a lower wiring layer, a via may be shown even though the via is located under the pattern of the wiring layer.

The standard cells C11, C12, and C13 may be respectively placed in a plurality of rows R11, R12, and R13. The number of standard cells included in the IC 10a is not limited thereto. Each of the rows R11, R12, and R13 may extend in the X-axis direction.

A plurality of lower power lines PL31 to PL34 may be placed on boundaries of the rows R11, R12, and R13. The lower power lines PL31 to PL34 may extend in the X-axis direction. The lower power lines PL31 to PL34 may include first lower power lines PL31 and PL33 providing a positive supply voltage VDD therethrough, and second lower power lines PL32 and PL34 providing a negative supply voltage VSS therethrough. The first lower power lines PL31 and PL33 and the second lower power lines PL32 and PL34 may be alternately placed in the Y-axis direction.

A plurality of upper power lines PL21 to PL24 may be connected to the lower power lines PL31 to PL34 through respective vias formed in a first via layer Vl. The upper power lines PL21 to PL24 may include first upper power lines PL21 and PL23 providing the positive supply voltage VDD therethrough, and second upper power lines PL22 and PL24 providing the negative supply voltage VSS therethrough. The first upper power lines PL21 and PL23 and the second upper power lines PL22 and PL24 may be alternately placed in the X-axis direction. The first upper power lines PL21 and PL23 may be connected to the first lower power lines PL31 and PL33, respectively, and the second upper power lines PL22 and PL24 may be connected to the second lower power lines PL32 and PL34, respectively.

The IC 10a according to an embodiment may include at least one upper power line between adjacent gate electrodes to form a power mesh structure between lower power lines and upper power lines and to stably supply power to standard cells through the power mesh structure.

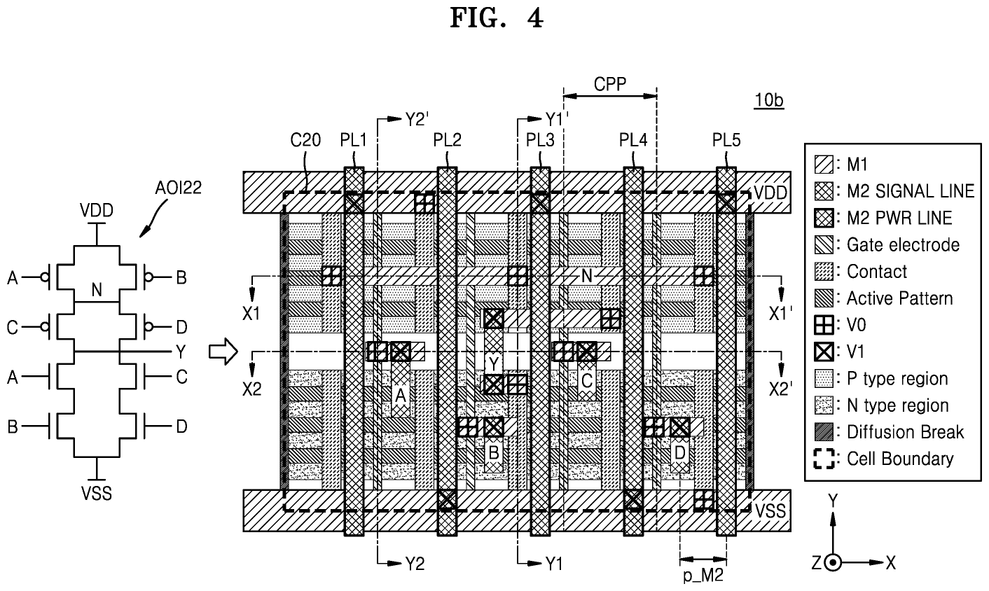

FIG. 4 is a layout diagram of a standard cell C20 according to an embodiment. Particularly, FIG. 4 is a top view, on the X-Y plane, of the IC 10b including the standard cell C20. Particularly, the left side of FIG. 4 shows a circuit diagram of a 2-2 AND-OR-inverter (AOI22), and the right side of FIG. 4 schematically shows, on a plane formed by the X-axis and the Y-axis, a layout of the standard cell C20 corresponding to the AOI22. Only some layers may be shown for convenience of drawing, and to indicate a connection between a pattern of a wiring layer and a pattern of a lower wiring layer, a via may be shown even though the via is located under the pattern of the wiring layer.

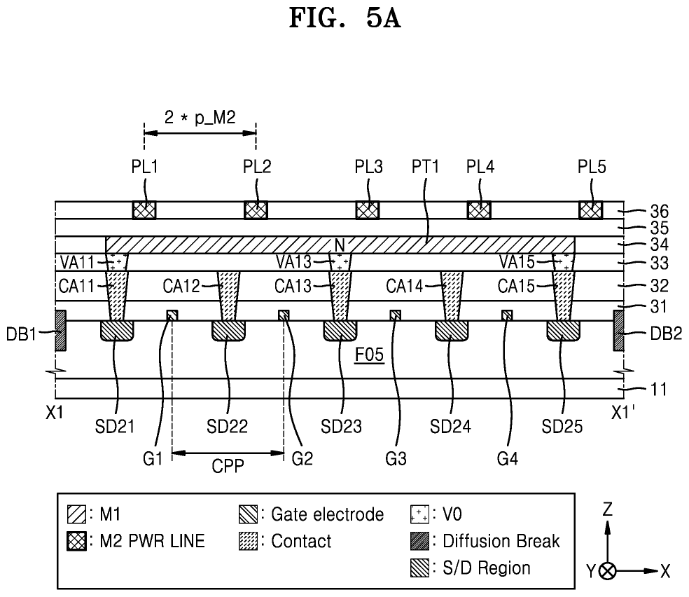

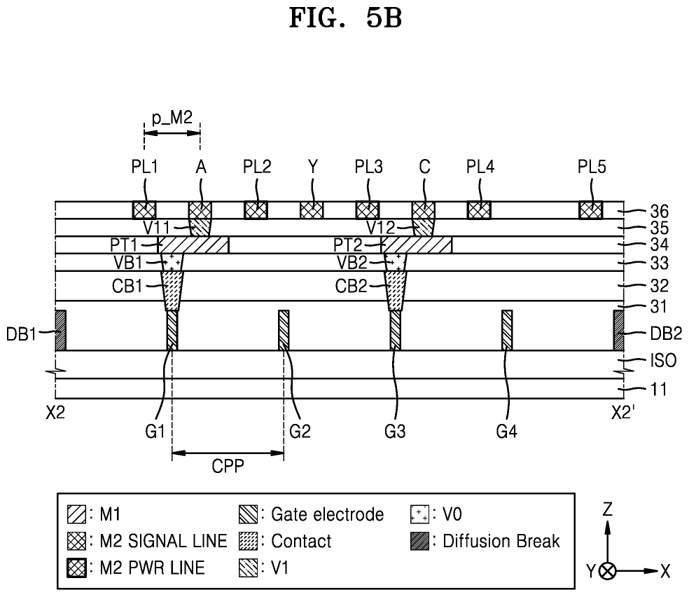

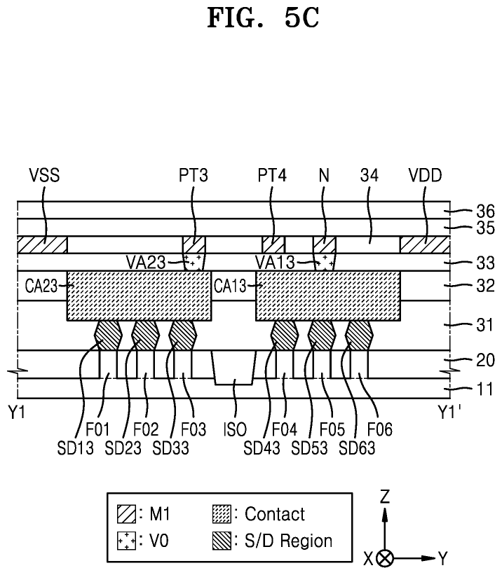

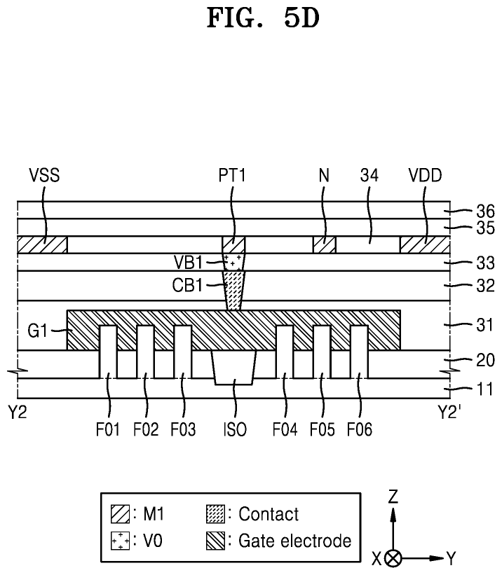

As shown in FIG. 4, at least one active pattern in an active region may extend in the X-axis direction, and the active pattern may intersect with a gate electrode extending in the Y-axis direction to form a transistor. When a fin-shaped active pattern extends in the X-axis direction, a transistor formed by the active pattern and a gate electrode may be referred to as a fin field effect transistor (FinFET). As described below with reference to FIGS. 5A to 5D, embodiments will be mainly described with reference to cells including a FinFET, but it would be understood that the embodiments are also applicable to cells including a transistor having a different structure from that of a FinFET. For example, the active pattern may include a plurality of nanosheets separated from each other in a Z-axis direction and extending in the X-axis direction, and a cell may include a multi-bridge channel FET (MBCFET) formed by the nanosheets and a gate electrode. Alternatively, a cell may include a ForkFET having a structure in which nanosheets for a P-type transistor and nanosheets for an N-type transistor are separated by a dielectric wall so that the N-type transistor is relatively close to the P-type transistor. Alternatively, a cell may include a vertical FET (VFET) having a structure in which source/drain regions are separated from each other in the Z-axis direction with a channel region therebetween, and a gate electrode encompasses the channel region. Alternatively, a cell may include an FET such as a complementary FET (CFET), a negative capacitance FET (NCFET), or a carbon nanotube (CNT) FET, a bipolar junction transistor, or other three-dimensional transistors.

As shown in FIG. 4, gate electrodes may be separated from each other with the first pitch CPP, and wirings formed in the second wiring layer M2 may be separated from each other with the second pitch p_M2.

As shown in FIG. 4, a plurality of upper power lines PL1 to PL5 may be placed to be adjacent to the first sides (e.g., left sides) of a plurality of gate electrodes. A plurality of signal lines, i.e., wirings through which input signals A, B, C, and D are received and a wiring through which an output signal Y is output, may be placed to be adjacent to the second sides (e.g., right sides) of the gate electrodes.

According to an embodiment, by placing a power line at the first side (e.g., left side) with reference to a gate electrode and placing a signal line at the second side (e.g., right side) with reference to the gate electrode, a wiring for routing and a wiring for power supply may be efficiently placed. That is, by placing power lines and signal lines at pre-defined locations, efficient routing performance and power supply performance may be provided.

FIGS. 5A to 5D are cross-sectional views of a structure of a standard cell according to an embodiment. Particularly, the cross-sectional view of FIG. 5A shows a cross-section of the standard cell C20 cut along X1-X1′ of FIG. 4, the cross-sectional view of FIG. 5B shows a cross-section of the standard cell C20 cut along X2-X2′ of FIG. 4, the cross-sectional view of FIG. 5C shows a cross-section of the standard cell C20 cut along Y1-Y1′ of FIG. 4, and the cross-sectional view of FIG. 5D shows a cross-section of the standard cell C20 cut along Y2-Y2′ of FIG. 4. Although not shown in FIGS. 5A to 5D, a gate spacer may be formed at a side surface of a gate electrode, and a gate dielectric layer may be formed between the gate electrode and the gate spacer and on a lower surface of the gate electrode. In addition, a barrier layer may be formed on the surface of a contact and/or a via. Hereinafter, FIGS. 5A to 5D will be described with reference to FIG. 4, and a duplicated description to be made with reference to FIGS. 5A to 5D will be omitted.

Referring to FIG. 5A, a substrate 11 may be bulk silicon or silicon-on-insulator (SOI) and may include, as a non-limiting example, silicon germanium (SiGe), silicon germanium on insulator (SGOI), indium antimonide (InSb), a lead telluride (PbTe) compound, indium arsenide (InAs), a phosphide, gallium arsenide (GaAs), gallium antimonide (GaSb), or the like. On the substrate 11, a fifth fin F05 may extend in the X-axis direction, and first to fifth source/drain regions SD21 to SD25 may be formed in the fifth fin F05. On the fifth fin F05, first to sixth interlayer insulating layers 31 to 36 may be formed. The first and second source/drain regions SD21 and SD22 along with the first gate electrode G1 may form a transistor, i.e., a p-type field effect transistor (PFET), the second and third source/drain regions SD22 and SD23 along with the second gate electrode G2 may form a PFET, the third and fourth source/drain regions SD23 and SD24 along with the third gate electrode G3 may form a PFET, and the fourth and fifth source/drain regions SD24 and SD25 along with the fourth gate electrode G4 may form a PFET.

First to fifth source/drain contacts CA11 to CA15 may be connected to the first to fifth source/drain regions SD21 to SD25 by passing through the second interlayer insulating layer 32. In some embodiments, at least one of the first to fifth source/drain contacts CA11 to CA15 may include a lower source/drain contact passing through the first interlayer insulating layer 31 and an upper source/drain contact passing through the second interlayer insulating layer 32. First to third source/drain vias VA11, VA13, and VA15 may be respectively connected to the first, third, and fifth source/drain contacts CA11, CA13, and CA15 by passing through the third interlayer insulating layer 33 and commonly connected to a pattern N formed in a first wiring layer M1. Accordingly, the pattern N may be electrically connected to the first source/drain region SD21 through the first source/drain via VA11 and the first source/drain contact CA11, electrically connected to the third source/drain region SD23 through the second source/drain via VA13 and the third source/drain contact CA13, and electrically connected to the fifth source/drain region SD25 through the third source/drain via VA15 and the fifth source/drain contact CA15. A layer in which the first to third source/drain vias VA11, VA13, and VA15 are formed may be referred to as a first via layer VO, and a layer in which the pattern N is formed may be referred to as the first wiring layer M1.

The upper power lines PL1 to PL5 may be separated from each other with double the second pitch p_M2. A layer in which the upper power lines PL1 to PL5 are formed may be referred to as the second wiring layer M2. The second pitch p_M2 may indicate a pitch between wirings formed in the second wiring layer M2. Double the second pitch p_M2 may be the same as the first pitch CPP. Referring to FIG. 5A, the gate electrodes G1 to G4 may be separated from each other with the first pitch CPP in the X-axis direction. Referring to FIG. 5A, the upper power lines PL1 to PL5 may be placed at pre-defined locations, and thus, the stability of power to be supplied to a standard cell may be improved.

Referring to FIG. 5B, a first gate contact CB1 may be connected to the first gate electrode G1 by passing through the second interlayer insulating layer 32, and a first gate via VB1 may be connected to the first gate contact CB1 and a first pattern PT1 by passing through the third interlayer insulating layer 33. The first pattern PT1 may be connected to an input pin A through a first via V11. Accordingly, the input pin A may be electrically connected to the first gate electrode G1. A second gate contact CB2 may be connected to the third gate electrode G3 by passing through the second interlayer insulating layer 32, and a second gate via VB2 may be connected to the second gate contact CB2 and a second pattern PT2 by passing through the third interlayer insulating layer 33. The second pattern PT2 may be connected to an input pin C through a second via V12. Accordingly, the input pin C may be electrically connected to the third gate electrode G3. In some embodiments, unlike shown in FIG. 5B, the first gate contact CB1 or the second gate contact CB2 may be omitted, and through a gate via passing through the second and third interlayer insulating layers 32 and 33, the input pin A may be electrically connected to the first gate electrode G1, and the input pin C may be electrically connected to the third gate electrode G3. On the fourth interlayer insulating layer 34, the fifth and sixth interlayer insulating layers 35 and 36 may be formed. A layer in which the sixth interlayer insulating layer 36 is formed may be referred to as the second wiring layer M2. In the second wiring layer M2, the upper power lines PL1 to PL5 and signal lines (e.g., the input pins A and C and an output pin Y) may be formed. As shown in FIG. 5B, an adjacent upper power line and signal line may be separated from each other based on the second pitch p_M2. A plurality of upper power lines and a plurality of signal lines may be alternately placed. However, the present embodiment is not limited thereto, and locations where the upper power lines and the signal lines are placed may be defined in advance, thereby improving routing performance and power supply performance of a plurality of standard cells included in an IC.

Referring to FIG. 5C, a field insulating layer 20 may be formed on the substrate 11. The field insulating layer 20 may include, as a non-limiting example, silicon dioxide (SiO₂), silicon nitride (SiN), silicon oxynitride (SiON), silicon oxycarbon nitride (SiOCN), or a combination thereof. In some embodiments, the field insulating layer 20 may encompass a portion of an active pattern, i.e., side surfaces of fins, as shown in FIG. 5C. On the field insulating layer 20, the first to sixth interlayer insulating layers 31 to 36 may be formed. First to sixth fins F01 to F06 may extend in the field insulating layer 20 in the X-axis direction, and six source/drain regions SD13 to SD63 may be formed on the first to sixth fins F01 to F06. Between the third and fourth fins F03 and F04, a device isolation layer ISO may extend in the X-axis direction.

A sixth source/drain contact CA23 may be connected to three source/drain regions SD13, SD23, and SD33 by passing through the second interlayer insulating layer 32, and accordingly, the three source/drain regions SD13, SD23, and SD33 may be electrically connected to one another. In addition, the third source/drain contact CA13 may be connected to three source/drain regions SD43, SD53, and SD63 by passing through the second interlayer insulating layer 32, and accordingly, the three source/drain regions SD43, SD53, and SD63 may be electrically connected to one another. A fourth source/drain via VA23 may be connected to the sixth source/drain contact CA23 by passing through the third interlayer insulating layer 33 and connected to a third pattern PT3. In addition, the second source/drain via VA13 may be connected to the third source/drain contact CA13 by passing through the third interlayer insulating layer 33, and connected to a node N.

A lower power line providing the positive supply voltage VDD to the first wiring layer M1 and a lower power line providing the negative supply voltage VSS to the first wiring layer M1 may extend in the X-axis direction.

Referring to FIG. 5D, the field insulating layer 20 may be formed on the substrate 11, and the first to sixth fins F01 to F06 passing through the field insulating layer 20 may intersect with the first gate electrode G1 extending in the Y-axis direction. The first gate electrode G1 may include, as a non-limiting example, titanium (Ti), tantalum (Ta), tungsten (W), aluminum (Al), cobalt (Co), or a combination thereof, or include a non-metal such as Si or SiGe. In addition, the first gate electrode G1 may be formed by stacking two or more conductive materials, for example, may include a work function control layer including titanium nitride (TiN), tantalum nitride (TaN), titanium carbide (TiC), tantalum carbide (TaC), titanium aluminum carbide (TiAlC), or a combination thereof and a peeling conductive layer including W, Al, or the like.

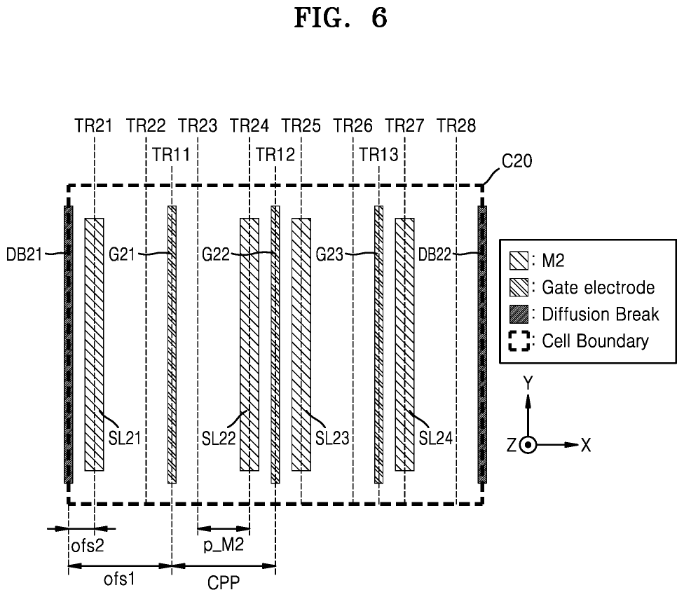

FIG. 6 is a layout diagram of the standard cell C20, according to an embodiment. Particularly, FIG. 6 is a top view, on the X-Y plane, of a placement of a plurality of gate electrodes, e.g., first to third gate electrodes G21 to G23, and a plurality of signal lines, e.g., first to fourth signal lines SL21 to SL24, included in the standard cell C20.

Referring to FIG. 6, the standard cell C20 may include the gate electrodes G21 to G23. A boundary of the standard cell C20 may be formed on cell separation structures DB21 and DB22. The cell separation structures DB21 and DB22 may be referred to as diffusion breaks.

The gate electrodes G21 to G23 may be aligned along the first tracks TR11, TR12, and TR13. In some embodiments, center lines of the gate electrodes G21 to G23 may be matched with the first tracks TR11, TR12, and TR13. The first tracks may be virtual lines to indicate locations of gate electrodes. The first tracks TR11, TR12, and TR13 may be separated from each other by the first pitch CPP.

The signal lines SL21 to SL24 may be aligned along at least one of the second tracks TR21 to TR28. In some embodiments, center lines of the signal lines SL21 to SL24 may be matched with the second tracks TR21, TR24, TR25, and TR27. The second tracks may be virtual lines to indicate locations of wirings formed in the second wiring layer M2. The second tracks TR21 to TR28 may be separated from each other with the second pitch p_M2. No signal line may be aligned on at least one of the second tracks TR21 to TR28, which is located between adjacent gate electrodes. That is, a track on which an upper power line is to be placed may be provided between adjacent gate electrodes. For example, the second tracks TR22, TR26, and TR28 among the second tracks TR21 to TR28 may be exclusively used for upper power lines.

Referring to FIG. 6, the first signal line SL21 may be placed at the second side (e.g., right side) of the cell separation structure DB21, the third signal line SL23 may be placed at the second side of the second gate electrode G22, and the fourth signal line SL24 may be placed at the second side of the third gate electrode G23. However, unlike shown in FIG. 2, the second signal line SL22 may be placed at the first side (e.g., left side) of the second gate electrode G22.

Regardless of which side of a gate electrode a signal line is placed at, at least one track to be exclusively used for an upper power line and at least one track to be exclusively used for a signal line may be formed between adjacent gate electrodes or an adjacent cell separation structure and gate electrode. For example, the second track TR21 to be exclusively used for the first signal line SL21 and the second track TR22 to be exclusively used for an upper power line may be formed between the cell separation structure DB21 and the first gate electrode G21. In addition, the second track TR23 to be exclusively used for the second signal line SL22 and the second track TR24 to be exclusively used for an upper power line may be formed between the first gate electrode G21 and the second gate electrode G22.

The standard cell C20 may be placed in one of a plurality of rows. For example, the standard cell C20 may be placed in at least one of the rows R11, R12, and R13 of FIG. 3. After placing the standard cell C20 in one of the rows, upper power lines may be aligned along exclusive tracks. For example, referring to FIG. 6, the upper power lines may be aligned along at least one of the second tracks TR22, TR26, and TR28. As shown in FIG. 3, the upper power lines may be connected to lower power lines extending in the X-axis direction to form a power distributed network (PDN).

According to an embodiment, a standard cell may have a space to be exclusively used for upper power lines, thereby decreasing a resistance of a PDN for supplying power to the standard cell, and supplying stable power to an IC.

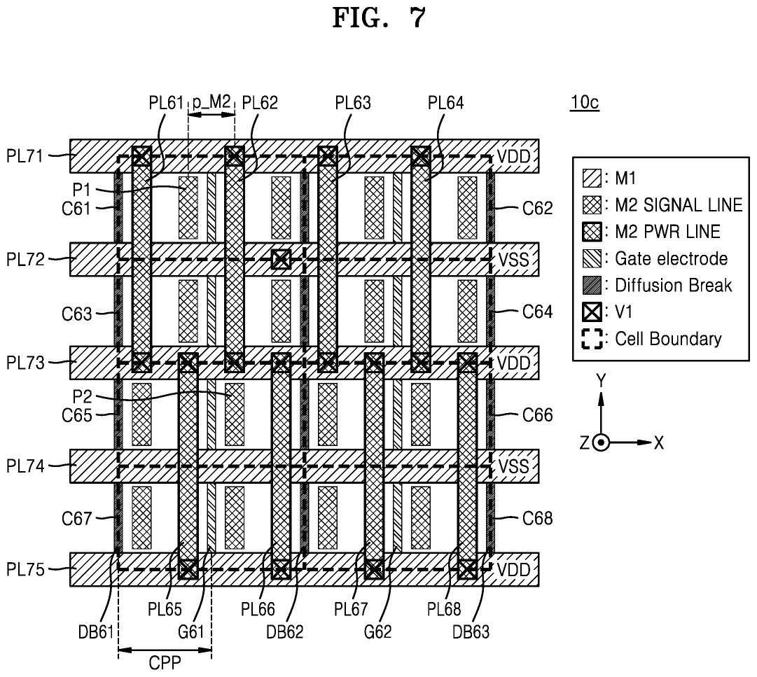

FIG. 7 is a layout diagram of a PDN according to an embodiment. Particularly, FIG. 7 is a top view, on the X-Y plane, of an IC 10c including a plurality of standard cells C61 to C68. Referring to FIG. 7, gate electrodes and wirings of the second wiring layer M2 may be placed according to a GR of 2:1. That is, a ratio of the first pitch CPP between the gate electrodes to the second pitch p_M2 between the wirings of the second wiring layer M2 may be 2:1. A plurality of lower power lines PL71 to PL75 may extend in the X-axis direction and provide the positive supply voltage VSS or the negative supply voltage VSS to the standard cells C61 to C68.

Referring to FIG. 7, first standard cells C61, C62, C63, and C64 may include signal lines (e.g., P1) formed at the first sides (e.g., left sides) of cell separation structures DB62, and DB63 and gate electrodes G61 and G62. Upper power lines PL61, PL62, PL63, and PL64 may be placed across the first standard cells C61, C62, C63, and C64 in the Y-axis direction. The upper power lines PL61, PL62, PL63, and PL64 may be placed at the second sides (e.g., right sides) of the cell separation structures DB61 and DB62 and the gate electrodes G61 and G62. That is, no signal lines may be placed at the second sides of the cell separation structures DB62, and DB63 and the gate electrodes G61 and G62, and the second sides of the cell separation structures DB62, and DB63 and the gate electrodes G61 and G62 may be exclusively used for the upper power lines PL61, PL62, PL63, and PL64. A mesh-shaped PDN may be formed by connecting the upper power lines PL61, PL62, PL63, and PL64 to first and third lower power lines PL71 and PL73.

Second standard cells C65, C66, C67, and C68 may include signal lines (e.g., P2) formed at the second sides (e.g., right sides) of the cell separation structures DB61 and DB62 and the gate electrodes G61 and G62. Upper power lines PL65, PL66, PL67, and PL68 may be placed across the second standard cells C65, C66, C67, and C68 in the Y-axis direction. The upper power lines PL65, PL66, PL67, and PL68 may be placed at the first sides (e.g., left sides) of the cell separation structures DB62, and DB63 and the gate electrodes G61 and G62. That is, no signal lines may be placed at the first sides of the cell separation structures DB62, and DB63 and the gate electrodes G61 and G62, and the first sides of the cell separation structures DB62, and DB63 and the gate electrodes G61 and G62 may be exclusively used for the upper power lines PL65, PL66, PL67, and PL68. A mesh-shaped PDN may be formed by connecting the upper power lines PL65, PL66, PL67, and PL68 to third and fifth lower power lines PL73 and L75.

The IC 10c according to an embodiment may include both second standard cells having upper power lines placed at the first sides with reference to gate electrodes or cell separation structures and first standard cells having upper power lines placed at the second sides with reference to the gate electrodes or the cell separation structures.

Thus far, the locations of the signal lines and the power lines in the X, Y and Z directions in the corresponding standard cells are described. Here, it is understood here that the vertical levels at which the signal lines, the upper power lines and the lower power lines described above are not limited to the vertical levels as described in the above embodiments. In other words, the signal lines, the upper power lines, and the lower power lines may be placed at vertical levels different from those described in the above embodiment. For example, opposite to the placement shown in FIGS. 5A-5D, the upper power lines PL1 to PL5 may be formed in a wiring layer lower than a wiring layer in which the lower power lines providing the positive supply voltage VDD and the negative supply voltage VSS are formed, according to embodiments. Also, the signal lines may also be formed in a wiring layer different from the wiring layer as shown in FIGS. 5A to 5D.

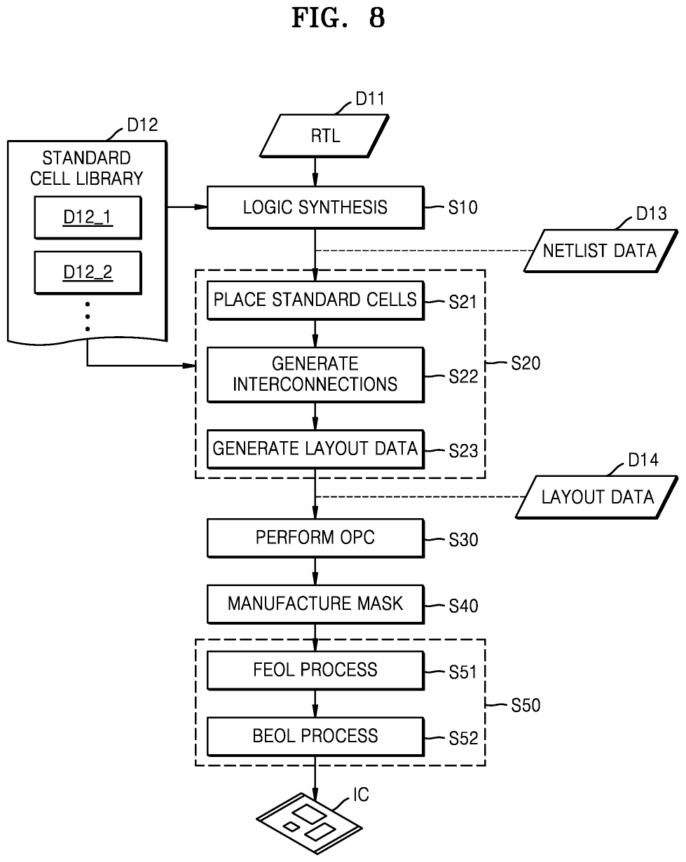

FIG. 8 is a flowchart of a method of fabricating an IC, according to an embodiment. A cell library (or a standard cell library) D12 may include information about cells, e.g., function information, characteristic information, and layout information. As shown in FIG. 8, the cell library D12 may include first data D12_1, second data D12_2, and the like which define layouts of a plurality of standard cells. For example, the first data D12_1 may define a layout of a first standard cell having signal lines formed at the first sides with reference to gate electrodes, and the second data D12_2 may define a layout of a second standard cell having signal lines formed at the second sides with reference to gate electrodes.

In operation S10, a logic synthesis operation of generating netlist data D13 from register transfer level (RTL) data D11 may be performed. For example, a semiconductor design tool (e.g., a logic synthesis tool) may generate the netlist data D13 including a bitstream or a netlist by performing logic synthesis on the RTL data D11 with reference to the cell library D12, the RTL data D11 being created by a hardware description language (HDL) such as a very high-speed integrated circuit (VHSIC) hardware description language (VHDL) or Verilog. The cell library D12 may include information about a height of a standard cell, the number of pins included in the standard cell, the number of tracks corresponding to the standard cell, and the like, and first and second standard cells may be included in an IC by referring to such information in a logic synthesis process.

In operation S20, a place and routing (P&R) operation of generating layout data D14 from the netlist data D13 may be performed. As shown in FIG. 8, the P&R operation (S20) may include a plurality of operations S21, S22, and S23.

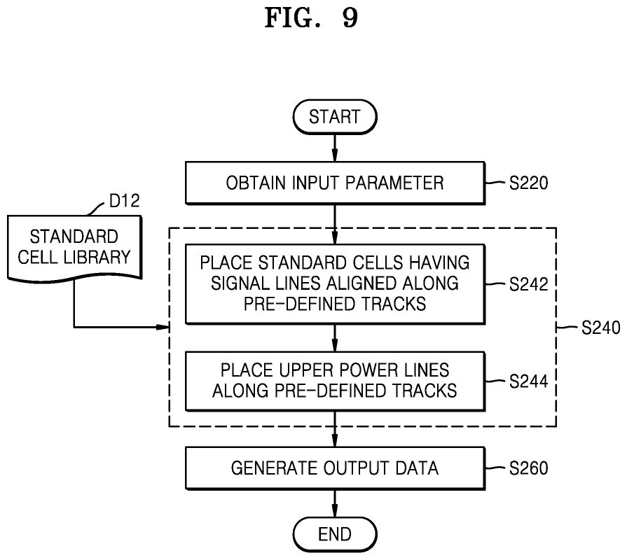

In operation S21, an operation of placing standard cells may be performed. For example, a semiconductor design tool (e.g., a P&R tool) may place a plurality of standard cells from the netlist data D13 with reference to the cell library D12. As described above, the semiconductor design tool may place the first and second standard cells. In operation S21, an operation of placing a plurality of power lines may be performed. For example, an operation of placing a plurality of lower power lines extending in the X-axis direction and a plurality of upper power lines extending in the Y-axis direction may be performed. A detailed method thereof may be described below with reference to FIG. 9.

In operation S22, an operation of generating interconnections may be performed. The interconnection may electrically connect an output pin to an input pin of a cell and include, for example, at least one via and at least one conductive pattern.

In operation S23, an operation of generating the layout data D14 may be performed. The layout data D14 may have, for example, a format such as generic or geometric data structure information interchange (GDSII) and include geometric information of the cells and the interconnections.

In operation S30, optical proximity correction (OPC) may be performed. OPC may indicate a work for forming a desired-shaped pattern by correcting a distortion phenomenon such as refraction caused by characteristics of light in photolithography included in a semiconductor process for fabricating an IC, and a pattern on a mask may be determined by applying OPC to the layout data D14. In some embodiments, a layout of an IC may be limitedly modified in operation S30, and the limited modification of the IC in operation S30 is post-processing for optimizing a structure of the IC and may be referred to as design polishing.

In operation S40, an operation of manufacturing a mask may be performed. For example, patterns on a mask may be defined to form patterns on a plurality of layers by applying OPC to the layout data D14, and at least one mask (or a photomask) for forming the respective patterns of the layers may be manufactured.

In operation S50, an operation of fabricating an IC may be performed. For example, the IC may be fabricated by using the at least one mask, manufactured in operation S40, to pattern a plurality of layers. As shown in FIG. 8, operation S50 may include operations S51 and S52.

In operation S51, a front-end-of-line (FEOL) process may be performed. The FEOL process may indicate a process of forming individual devices, e.g., transistors, capacitors, and resistors, on a substrate in a process of fabricating an IC. For example, the FEOL process may include planarizing and cleaning a wafer, forming a trench, forming a well, forming a gate electrode, forming a source and a drain, and the like.

In operation S52, a back-end-of-line (BEOL) process may be performed. The BEOL process may indicate a process of interconnecting individual devices, e.g., transistors, capacitors, and resistors, in a process of fabricating an IC. For example, the BEOL process may include silicidation of gate, source, and drain regions, adding a dielectric, performing planarization, forming a hole, adding a metal layer, forming a via, forming a passivation layer, and the like. Thereafter, the IC may be packaged in a semiconductor package and used as a component of various applications.

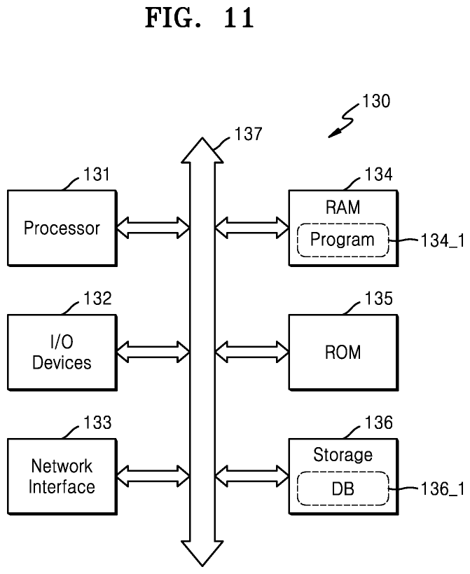

FIG. 9 is a flowchart of a method of designing an IC, according to an embodiment. The method of FIG. 9 may be performed by a computing system (e.g., 130 of FIG. 11) including at least one processor configured to execute a series of instructions. As shown in FIG. 9, the method of designing an IC may include operations S220, S240, and S260.

In operation S220, an operation of obtaining input data may be performed. The input data may indicate data defining the IC, and include, for example, the netlist data D13 described above with reference to FIG. 8. The netlist data D13 may include information about cells and interconnections included in the IC.

In operation S240, a P&R operation may be performed based on a cell library D12. Operation S240 may correspond to operations S21 and S22 of FIG. 8. Operation S240 may include a plurality of operations S242 and S244. In operation S242, an operation of placing standard cells having signal lines aligned along pre-defined tracks may be performed. For example, an operation of placing first standard cells having signal lines adjacent to the first sides (e.g., left sides) of gate electrodes or second standard cells having signal lines adjacent to the second sides (e.g., right sides) of the gate electrodes may be performed. The first standard cell may be a standard cell in which no signal lines are placed at the second sides of the gate electrodes. In operation S244, upper power lines may be placed at the second sides of the gate electrodes included in the first standard cells. The second standard cell may be a standard cell in which no signal lines are placed at the first sides of the gate electrodes. In operation S244, upper power lines may be placed at the first sides of the gate electrodes included in the second standard cells. The present embodiment is not limited thereto, and in operation S240, standard cells in which a track or space to be exclusively used for an upper power line is provided between adjacent gate electrodes may be placed.

In operation S244, an operation of placing upper power lines along pre-defined tracks may be performed. As described above with reference to FIGS. 1 to 7, the upper power lines may extend in the Y-axis direction. The upper power lines may be formed in the second wiring layer M2. The upper power lines may be connected to lower power lines extending in the X-axis direction. The lower power lines may be formed in the first wiring layer M1. The upper power lines may be placed to be adjacent to the first sides or the second sides of gate electrodes. At least one upper power line may be placed between adjacent gate electrodes. In the method of designing an IC, according to an embodiment, by placing the upper power lines along pre-defined tracks, a mesh-shaped PDN may be formed together with the lower power lines. Therefore, the method of designing an IC, according to an embodiment, may supply stable power to standard cells.

In operation S260, an operation of generating output data may be performed. The output data may indicate data defining a layout of the IC and include, for example, the layout data D14 described above with reference to FIG. 8. The output data may define a layout of an IC in which at least one upper power line is placed for each adjacent gate electrode.

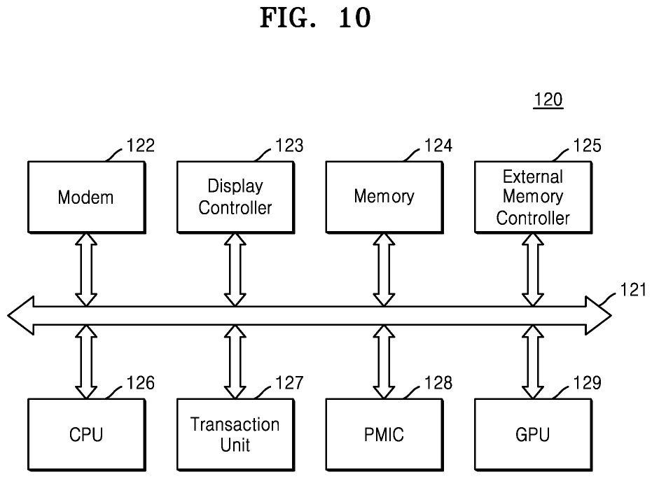

FIG. 10 is a block diagram of a system on chip (SoC) 120 according to an embodiment. The SoC 120 is a semiconductor device and may include an IC according to an embodiment. The SoC 120 is obtained by implementing, in a single chip, complicated functional blocks, such as an intellectual property (IP) block, for performing various functions, and according to embodiments, upper power lines placed at pre-defined locations with reference to gate electrodes may be included in the respective functional blocks in the SoC 120, and accordingly, the SoC 120 capable of stably supplying power to standard cells may be achieved.

Referring to FIG. 10, the SoC 120 may include a modem 122, a display controller 123, a memory 124, an external memory controller 125, a central processing unit (CPU) 126, a transaction unit 127, a power management integrated circuit (PMIC) 128, and a graphics processing unit (GPU) 129, and the functional blocks of the SoC 120 may communicate with each other via a system bus 121. According to an embodiment, each of these components of the SoC 120 may include one or more ICs described according to the above embodiments.

The CPU 126 capable of generally controlling an operation of the SoC 120 may control operations of the other functional blocks, that is, the modem 122, the display controller 123, the memory 124, the external memory controller 125, the CPU 126, the transaction unit 127, the PMIC 128, and the GPU 129. The modem 122 may demodulate a signal received from the outside of the SoC 120, or modulate a signal generated inside the SoC 120 and transmit the modulated signal to the outside. The external memory controller 125 may control an operation of transmitting and receiving data to and from an external memory device connected to the SoC 120. For example, a program and/or data stored in the external memory device may be provided to the CPU 126 or the GPU 129 under control of the external memory controller 125. The GPU 129 may execute program instructions associated with graphics processing. The GPU 129 may receive graphic data through the external memory controller 125 and transmit graphic data processed by the GPU 129 to the outside of the SoC 120 through the external memory controller 125. The transaction unit 127 may monitor a data transaction of each functional block, and the PMIC 128 may control power to be supplied to each functional block, under control of the transaction unit 127. The display controller 123 may transmit data generated inside the SoC 120 to a display (or a display device) outside the SoC 120 by controlling the display.

The memory 124 may include a nonvolatile memory such as electrically erasable programmable read-only memory (EEPROM), flash memory, phase change random access memory (PRAM), resistance random access memory (RRAM), nano floating gate memory (NFGM), polymer random access memory (PoRAM), magnetic random access memory (MRAM), or ferroelectric random access memory (FRAM) or a volatile memory such as dynamic random access memory (DRAM), static random access memory (SRAM), mobile DRAM, double data rate synchronous dynamic random access memory (DDR SDRAM), low power DDR (LPDDR) SDRAM, graphic DDR (GDDR) SDRAM, or Rambus dynamic random access memory (RDRAM).

FIG. 11 is a block diagram of a computing system 130 including a memory storing a program, according to an embodiment. At least some of operations included in a method of fabricating an IC (e.g., the method of FIG. 8) and operations included in a method of designing an IC (e.g., the method of FIG. 9), according to embodiments, may be performed by the computing system 130.

The computing system 130 may be a stationary computing system such as a desktop computer, a workstation, or a server or a portable computing system such as a laptop computer. As shown in FIG. 11, the computing system 130 may include a processor 131, input/output devices 132, a network interface 133, random access memory (RAM) 134, read only memory (ROM) 135, and a storage 136. The processor 131, the input/output devices 132, the network interface 133, the RAM 134, the ROM 135, and the storage 136 may be connected to a bus 137 and communicate with each other via the bus 137.

The processor 131 may be referred to as a processing unit and include at least one core, e.g., a micro-processor, an application processor (AP), a digital signal processor (DSP), and a GPU, capable of executing an arbitrary instruction set (e.g., Intel Architecture-32 (IA-32), 64-bit extended IA-32, x86-64, PowerPC, Sparc, million instructions per second (MIPS), advanced RISC (reduced instruction set computer) machine (ARM), or IA-64). For example, the processor 131 may access a memory, i.e., the RAM 134 or the ROM 135, via the bus 137 and execute instructions stored in the RAM 134 or the ROM 135.

The RAM 134 may store a program 134_1 for fabricating an IC, according to an embodiment, or at least a portion of the program 134_1, and the program 134_1 may allow the processor 131 to perform at least some of operations included in the method of fabricating an IC (e.g., the method of FIG. 8) and operations included in the method of designing an IC (e.g., the method of FIG. 9). That is, the program 134_1 may include a plurality of instructions executable by the processor 131, and the instructions included in the program 134_1 may allow the processor 131 to perform at least some of the operations included in, for example, the flowcharts described above with reference to FIGS. 8 and 9.

The storage 136 may not lose stored data even when power supplied to the computing system 130 is cut off. For example, the storage 136 may include a nonvolatile memory device or a storage medium such as magnetic tape, an optical disc, or a magnetic disc. In addition, the storage 136 may be detachable from the computing system 130. The storage 136 may store the program 134_1 according to an embodiment, and the program 134_1 or at least a portion of the program 134_1 may be loaded from the storage 136 to the RAM 134 before the program 134_1 is executed by the processor 131. Alternatively, the storage 136 may store a file created by a program language, and the program 134_1 generated from the file by a compiler or the like or at least a portion of the program 134_1 may be loaded to the RAM 134. In addition, as shown in FIG. 11, the storage 136 may include a database 136_1, and the database 136_1 may contain information required to design an IC, e.g., the standard cell library D12 of FIG. 8.

The storage 136 may store data to be processed by the processor 131 or data processed by the processor 131. That is, the processor 131 may generate data by processing data stored in the storage 136 and store the generated data in the storage 136, according to the program 134_1. For example, the storage 136 may store the RTL data D11, the netlist data D13, and/or the layout data D14 of FIG. 8.

The input/output devices 132 may include input devices such as a keyboard and a pointing device and include output devices such as a display device and a printer. For example, through the input/output devices 132, a user may trigger execution of the program 134_1 by the processor 131, input the RTL data D11 and/or the netlist data D13 of FIG. 8, and check the layout data D14 of FIG. 8.

The network interface 133 may provide access to a network outside the computing system 130. For example, the network may include a plurality of computing systems and communication links, and the communication links may include wired links, optical links, radio links, or other arbitrary-types of links.

It is understood that the structures of a standard cell described above may also apply to a semiconductor cell which is not a standard cell.

While the inventive concept has been particularly shown and described with reference to embodiments thereof, it will be understood that various changes in form and details may be made therein without departing from the spirit and scope of the following claims.

1. An integrated circuit (IC) comprising a standard cell, the IC comprising:
a plurality of gate electrodes extending in a first direction and arranged in a second direction that is orthogonal to the first direction;
a plurality of first power lines extending in the first direction to supply power to the standard cell, and respectively placed to be adjacent to first sides of the gate electrodes; and
a plurality of signal lines extending in the first direction to transfer an input signal or an output signal of the standard cell, and respectively placed to be adjacent to second sides of the gate electrodes.

2. The IC of claim 1, further comprising a plurality of second power lines extending in the second direction to supply power to the standard cell, placed in a wiring layer below or above a wiring layer in which the first power lines are placed, and connected to the first power lines.

3. The IC of claim 2, wherein the signal lines and the first power lines are placed in a same wiring layer.

4. The IC of claim 1, wherein the signal lines and the first power lines are alternately placed in the second direction.

5. The IC of claim 4, wherein the signal lines and the first power lines are not placed on the gate electrodes.

6. The IC of claim 1, wherein the gate electrodes are arranged in the second direction at a first pitch,
wherein the signal lines and the first power lines are arranged in the second direction at a second pitch, and
wherein the first pitch is greater than the second pitch.

7. The IC of claim 6, wherein the first pitch is double the second pitch.

8. The IC of claim 6, wherein a leftmost gate electrode among the gate electrodes is separated from a left boundary of the standard cell by a first offset in the second direction,
wherein a leftmost signal line among the signal lines or a leftmost first power line among the first power lines is separated from the left boundary of the standard cell by a second offset in the second direction,
wherein the first offset is the same as the first pitch, and
wherein the second offset is the same as the second pitch.

9. The IC of claim 1, further comprising a cell separation structure by which the standard cell is separated from another standard cell adjacent to the standard cell in the second direction,
wherein at least one of the first power lines is placed to be adjacent to a second side of the cell separation structure, and
wherein at least one of the signal lines is placed to be adjacent to a first side of the cell separation structure.

10. An integrated circuit (IC) comprising a plurality of standard cells, the IC comprising:
a plurality of gate electrodes aligned along a plurality of first tracks extending in a first direction and arranged in a second direction orthogonal to the first direction;
at least one signal line aligned along at least one second track, respectively, located at a pre-defined side of at least one of the gate electrodes, among a plurality of second tracks extending in the first direction and arranged in the second direction, to transfer an input signal or an output signal of the standard cells; and
at least one first power line aligned along at least one of the second tracks except the second track located at the pre-defined side, to supply power to the standard cells.

11. The IC of claim 10, wherein the signal line and the first power line do not overlap the gate electrodes.

12. The IC of claim 10, further comprising a plurality of second power lines extending in the second direction to supply power to the standard cells,
wherein the first power line is formed in a wiring layer located higher than the second power lines.

13. The IC of claim 10, wherein the gate electrodes are arranged in the second direction at a first pitch,
wherein the signal line and the first power line are separated from each other in the second direction by a second pitch, and
wherein the first pitch is greater than the second pitch.

14. The IC of claim 13, wherein the first power line comprises a plurality first power lines arranged in the second direction at double the second pitch.

15. The IC of claim 10, further comprising a cell separation structure by which the standard cell is separated from another standard cell adjacent to the standard cell in the second direction,
wherein a first track, adjacent to the cell separation structure, among the first tracks is separated from the cell separation structure by a first offset in the second direction, and
wherein a second track, adjacent to the cell separation structure, among the second tracks is separated from the cell separation structure by a second offset in the second direction

16-20. (canceled)

21. An integrated circuit (IC) comprising a semiconductor cell, the semiconductor cell comprising:
a plurality gate electrodes arranged in a first direction on a substrate;
a plurality power lines disposed at a plurality of first sides, respectively, of the gate electrodes in parallel with the gate electrodes, and configured to transfer power to the semiconductor cell; and
a plurality signal lines disposed at a plurality second sides, respectively, of the gate electrodes in parallel with the gate electrodes, and configured to transfer an input signal or an output signal of the semiconductor cell,
wherein the first sides and the second side are positioned at left sides and right sides of the gate electrodes, respectively, or right sides and left sides of the gate electrodes, respectively.

22. The IC of claim 21, further comprising a cell separation structure disposed at a left or right end of the semiconductor cell in parallel with the gate electrodes to separate the semiconductor cell from an adjacent semiconductor cell,
wherein a first offset between the cell separation structure and a leftmost or rightmost gate electrode, among the gate electrodes, is the same as a first pitch at which the gate electrodes are arranged in a horizontal direction, and
wherein at least one of the power lines and at least one of the signal lines are disposed between the cell separation structure and the leftmost or rightmost gate electrode.

23. The IC of claim 22, wherein one of the first power line and the signal line disposed closer to the cell separation structure among the first power line and the signal line is separated from the cell separation structure by a second offset, and
wherein the second offset is the same as a second pitch at the power lines and the signal lines are arranged in the horizontal direction.

24. The IC of claim 23, wherein the first offset is greater than the second offset.

25. The IC of claim 22, further comprising another cell separation structure disposed at the left or right end of the semiconductor cell with the gate electrodes therebetween,
wherein the other cell separation structure is separated from the leftmost or rightmost gate electrode by the first offset, and
wherein another at least one of the power lines and another at least one of the signal lines are disposed between the other cell separation structure and the leftmost or rightmost gate electrode.
